(19) United States
(12) Patent Application Publication
(10) Pub. No.: US 2014/0264328 A1
(43) Pub. Date: Sep. 18, 2014

(54) SEMICONDUCTOR ELEMENT

(71) Applicant: PANASONIC CORPORATION, Osaka (JP)

(72) Inventors: Mikihiko NISHITANI, Nara (JP); Masahiro SAKAI, Kyoto (JP); Masumi IZUCHI, Osaka (JP); Yusuke FUKUI, Nara (JP); Yasuhiro YAMAUCHI, Osaka (JP)

(73) Assignee: PANASONIC CORPORATION, Osaka (JP)

(21) Appl. No.: 14/287,750

(22) Filed: May 27, 2014

Related U.S. Application Data
(63) Continuation of application No. PCT/JP2012/007532, filed on Nov. 22, 2012.

(30) Foreign Application Priority Data
Nov. 28, 2011 (JP) 2011-258452

(51) Int. Cl. H01L 29/24

(52) U.S. Cl. CPC H01L 29/24
USPC 257/43

(57) ABSTRACT

Provided is a semiconductor element including a p-type semiconductor layer that is used in combination with an n-type ZnO-based semiconductor layer, and that can be formed, even at relatively low temperature, to have a small thickness, high crystallinity, and surface smoothness. The semiconductor element is expected to achieve high performance when used for a large-screen display. Specifically, the semiconductor element includes: a glass substrate; a lower electrode; a ZnO active layer (n-type semiconductor layer) having a thickness of 2 um to 4 um; a p-type ZnNiO layer (first p-type semiconductor layer) made of a p-type semiconductor material of Zn_{0.5}Ni_{0.5}O and having a thickness of 200 nm to 400 nm; a p-type NiO layer (second p-type semiconductor layer); and an upper electrode made of a transparent electrode material such as ITO, which are sequentially formed in the stated order.

### CROSS REFERENCE TO RELATED APPLICATION

This is a continuation application of PCT Application No. PCT/JP2012/007532 filed Nov. 22, 2012, designating the United States of America, the disclosure of which, including the specification, drawings and claims, is incorporated herein by reference in its entirety.

### TECHNICAL FIELD

The present disclosure relates to a semiconductor element using a zinc oxide (ZnO)-based material.

### BACKGROUND ART

A ZnO crystal is a direct transition semiconductor having a wide band gap of approximately 3.37 eV. A ZnO crystal is inexpensive and environmentally-friendly. Also, the binding energy of an exciton inside a ZnO crystal is 60 meV. Here, the exciton is the combination of a hole and an electron. Due to this large binding energy, a ZnO crystal exists stably even at room temperature. For this reason, a ZnO crystal is expected to serve as a material for a light-emitting device that emits light in the range of a blue region to an ultraviolet region. A ZnO crystal does not only serve as a material for a light-emitting device but are also used for various other purposes. For example, a ZnO crystal can be applied to a light-receiving element, a piezoelectric element, a transistor, a transparent electrode, etc.

In order to use a ZnO crystal for such purposes, it is beneficial to establish a ZnO crystal growth technology which realizes mass production and high quality. It is also beneficial to establish a doping technology for controlling the conductivity of a semiconductor.

In particular, in the case of development of a ZnO device including an n-type ZnO semiconductor layer and a p-type ZnO-based semiconductor layer disposed on the n-type ZnO semiconductor layer, it is a major challenge to form the p-type ZnO-based semiconductor layer. At present, a large number of institutions have been devoting their energies to forming a p-type ZnO-based semiconductor layer.

For example, to form a ZnO-based semiconductor, many institutions have studied a method of using a group V element as a p-type doping material to be doped into ZnO, and substituting the atoms of the group V element for oxygen atoms. Examples of group V elements used as a p-type doping material include nitrogen (N), arsenic (As), phosphorus (P), and antimony (Sb). In group V elements, N is a strong candidate for a p-type dopant used for ZnO, since the ionic radius of N is approximately the same as that of oxygen.

Meanwhile, there is a demand for a ZnO device that is a light-emitting device suitable for a large-screen display. Accordingly, a technology is required that allows formation of a light-emitting device, which is made up of an n-type ZnO semiconductor film and a p-type semiconductor thin film formed thereon, on a substrate that can be easily made large, such as a glass substrate. (Patent Literature 2).

### CITATION LIST

### Patent Literature

### [Patent Literature 1]

Japanese Patent Application Publication No. 2005-223219

### [Patent Literature 2]

Japanese Patent Application Publication No. 2003-273400

### SUMMARY OF INVENTION

### Technical Problem

Here, in order to achieve high performance in a large-screen display having a ZnO-based semiconductor, it is beneficial for a p-type semiconductor film, which is formed by doping ZnO with, for example, nitrogen, to have high crystallinity and surface smoothness. To achieve high crystallinity and surface smoothness, it is beneficial for the p-type semiconductor film to undergo an anneal treatment at a high temperature of approximately 300° C. to 800° C. However, since a glass substrate cannot withstand such a high temperature, it is difficult to form a p-type ZnO-based semiconductor film on a glass substrate using a nitrogen doping method.

On the other hand, an NiO thin film, which is well-known as a useful semiconductor material, can be formed as a p-type semiconductor film relatively easily at low temperature. Accordingly, a semiconductor formed with a mixed crystal material (ZnNiO) including ZnO and NiO is also proposed. However, an NiO thin film has the following problem. That is, although an NiO thin film is a promising p-type material that allows for formation of a p-type semiconductor film in large area and at low room temperature, the offset between the valence band of the NiO thin film and the valence band of an n-type ZnO-based semiconductor is approximately 2 eV, which is quite large. Accordingly, if a semiconductor is configured from a combination of a ZnNiO thin film and an n-type ZnO-based semiconductor, and the semiconductor thus configured is used as a current-injection light-emitting device, the hole injection efficiency is lowered.

In addition, the hole concentration of a thin film made of a mixed crystal, such as ZnNiO, is lower than the hole concentration of an NiO thin film. This is because the hole concentration of the ZnNiO thin film rapidly decreases with an increase in a ZnO component. Accordingly, if a current-injection light-emitting device is configured from a combination of a mixed crystal film and an n-type ZnO-based semiconductor, such a device also has low hole injection efficiency.

As described above, there is still room for improvement in order to achieve high performance in a semiconductor using a ZnO material.

In view of the above problem, one non-limiting and exemplary embodiment provides a semiconductor element including a p-type semiconductor layer that is used in combination with an n-type ZnO-based semiconductor layer, and that can be formed to have a small thickness, high crystallinity, and surface smoothness even at relatively low temperature. The semiconductor element including such a p-type semiconductor layer is expected to achieve high performance even when the semiconductor is used for a large-screen display.

### Solution to Problem

In order to solve the above problem, one general aspect of the present disclosure is a semiconductor element comprising: an n-type semiconductor layer made of ZnO; a first p-type semiconductor layer that is on the n-type semiconductor layer and is made of Zn_{1-X}Ni_{X}O where 0<X<1; and a second p-type semiconductor layer that is on the first p-type semiconductor layer and is made of Zn_{1-Y}Ni_{Y}O where 0<Y≦1, wherein Y is greater than X.

### Advantageous Effects of Invention

According to one aspect of the present disclosure as described above, the semiconductor element includes a p-type semiconductor layer that is used in combination with an n-type ZnO-based semiconductor layer, and that can be formed to have high crystallinity and surface smoothness even at relatively low temperature. This makes it possible to provide a semiconductor element that is expected to achieve high performance even when the semiconductor is used for a large-screen display.

### BRIEF DESCRIPTION OF DRAWINGS

FIG. 1 is a schematic sectional view showing the structure of a semiconductor element (p-n heterojunction element) 1X including a first p-type semiconductor layer 4a made of a Zn₁₋ₓMₓO-based material.

FIG. 2 is a schematic sectional view showing the structure of a semiconductor element 1 according to Embodiment 1.

FIG. 3 is a graph showing a result of XPS measurement performed on a ZnO thin film, a Zn_{0.5}Ni_{0.5}O thin film, and an NiO thin film.

FIG. 4 shows the relationship between the value X in a Zn₁₋ₓNiₓO thin film, and a band gap and offset between the Zn₁₋ₓNiₓO thin film and the ZnO thin film.

FIG. 5 shows a result of measurement of the resistivity of the Zn₁₋ₓNiₓO thin film while the value X is changed.

FIG. 6 shows a result of a theoretical calculation concerning the conductance of holes in a semiconductor element.

FIG. 7 is a schematic view showing the structures of semiconductor elements used for the evaluation of a hole injection amount.

FIG. 8 shows the current-voltage characteristics of the semiconductor elements.

### DESCRIPTION OF EMBODIMENTS

### <Aspects of Disclosure>

One aspect of the present disclosure is a semiconductor element comprising: an n-type semiconductor layer made of ZnO; a first p-type semiconductor layer that is on the n-type semiconductor layer and is made of Zn_{1-X}Ni_{X}O where 0<X<1; and a second p-type semiconductor layer that is on the first p-type semiconductor layer and is made of Zn_{1-Y}Ni_{Y}O where 0<Y≦1, wherein Y is greater than X.

According to another aspect of the present disclosure, an amount of NiO in the first p-type semiconductor layer may be in a range of at least 30 mol % to less than 100 mol %.

According to another aspect of the present disclosure, X in the Zn_{1-X}Ni_{X}O of the first p-type semiconductor layer may be in a range of 0<X≦0.65.

According to another aspect of the present disclosure, X in the Zn_{1-X}Ni_{X}O of the first p-type semiconductor layer may be in a range of 0.3≦X≦0.65.

According to another aspect of the present disclosure, X in the Zn_{1-X}Ni_{X}O of the first p-type semiconductor layer may be in a range of 0.45≦X≦0.55.

According to another aspect of the present disclosure, Y in the Zn_{1-Y}Ni_{Y}O of the second p-type semiconductor layer may be 1.

According to another aspect of the present disclosure, an offset between a top of a valence band of the first p-type semiconductor layer and a top of a valence band of the n-type semiconductor layer may be less than 1 eV.

According to another aspect of the present disclosure, a hole concentration of the second p-type semiconductor layer may be at least 1×10¹⁷ cm⁻³.

### <Light-Emitting Material>

### (P-Type Semiconductor Material Made of Zn, M, and O)

The following describes a p-type semiconductor material according to the present disclosure.

As a result of an intensive study, the present inventors found that a p-type semiconductor material having a composition that includes zinc, oxygen, and an element having a 3d electron at the outermost shell and having an energy level higher at a 3d orbital than at a 4s orbital is suitable for use in film formation at low temperature. With this p-type semiconductor material, a p-type semiconductor thin film having a low resistance can be formed either on a substrate or on an n-type semiconductor layer at a relatively low temperature of at most 500° C. This allows for the use of a glass substrate during formation of the p-type semiconductor thin film.

In addition, the present inventors found that, by stacking a layer made of the p-type semiconductor material on an n-type ZnO layer, a light-emitting device having a heterojunction between the p-type semiconductor layer and the n-type ZnO layer is formed. Such a light-emitting device can emit light having a luminescent color in the range of the blue region to the ultraviolet region.

In order to form a thin film with the aforementioned p-type semiconductor material, a mixed material composed of ZnO and MO (M being an element having a 3d electron at the outermost shell and having an energy level higher at the 3d orbital than at the 4s orbital) may be used as a sputtering target and placed on a substrate or a ZnO layer, and, in that state, sputtering may be performed on the sputtering target.

Note that, if the formation of the thin film is performed in a reducing atmosphere, the resulting film is likely to be an n-type semiconductor film. Accordingly, it is desirable that the formation of the thin film be performed in an oxidizing atmosphere, so that the resulting film will be a p-type semiconductor film.

The semiconductor material having the aforementioned composition has the properties of a p-type semiconductor. This is presumably because when an element having a 3d electron at the outermost shell and having an energy level higher at the 3d orbital than at the 4s orbital is mixed with ZnO, holes are more likely to be formed at the 4s orbital of the semiconductor material.

It is desirable that the composition of the p-type semiconductor material be represented by Zn₁₋ₓMₓO (M being an element having a 3d electron at the outermost shell and having an energy level higher at the 3d orbital than at the 4s orbital) where 0<X<1.

Zn₁₋ₓMₓO is an oxide of ZnO and MO, where X denotes the ratio of the number of moles of M to the total number of moles of Zn and M.

The p-type semiconductor material may be in a non-crystalline state; however, it is desirable that the p-type semiconductor material be a crystalline compound so as to obtain excellent properties.

Concerning the crystalline compound, the p-type semiconductor material may be a mixed crystal resulting from Zn in a ZnO crystal being partially substituted by M, or mixed crystal resulting from M in an MO crystal being partially substituted by Zn, or a crystal mixture composed of a mix of a ZnO crystal and an MO crystal.

Examples of an element having a 3d electron at the outermost shell and having an energy level higher at the 3d orbital than at the 4s orbital) include Ni and Cu.

### <Structure of Semiconductor Element>

### (Semiconductor Element 1X)

FIG. 1 is a schematic sectional view showing the structure of a semiconductor element (p-n heterojunction element) 1X made of a p-type semiconductor material.

As shown in FIG. 1, the semiconductor element 1X includes a glass substrate 10, a lower electrode 2, an n-type semiconductor layer 3, a first p-type semiconductor layer 4a, and an upper electrode 5.

The glass substrate 10 has a thickness of approximately 0.5 mm. The lower electrode 2 is formed on the glass substrate 10. The lower electrode 2 is made of a transparent electrode material, such as ITO, and has a thickness of approximately 100 nm. The n-type semiconductor layer 3 is formed on the lower electrode 2. The n-type semiconductor layer 3 serves as an active layer made of ZnO, and has a thickness of 2 um to 4 um. The first p-type semiconductor layer 4a is formed on the n-type semiconductor layer 3, and has a thickness of 200 nm to 400 nm. Note that the first p-type semiconductor layer 4a is made of a Zn₁₋ₓMₓO-based material (0<X<1) which is a p-type semiconductor material according to the present disclosure discussed above. The upper electrode 5 is formed on the p-type semiconductor layer 4a. The upper electrode 5 is made of a transparent electrode material, such as ITO, and has a thickness of approximately 100 nm. Since the upper electrode 5 is transparent, light emitted from the semiconductor element 1X during driving thereof can be extracted from the top surface of the semiconductor element 1X as well.

The first p-type semiconductor layer 4a can be made of a Zn₁₋ₓNiₓO thin film. Zn₁₋ₓNiₓO is an oxide of ZnO and NiO, where X denotes the ratio of the number of moles of Ni to the total number of moles of Zn and Ni.

Zn₁₋ₓNiₓO can be a compound resulting from Zn in ZnO being partially substituted by Ni, or a compound resulting from Ni in NiO being partially substituted by Zn.

The crystal form of Zn₁₋ₓNiₓO may be a mixed crystal form consisting of a crystal of ZnO (Wurtzite type) and a crystal of NiO (NaCl type), a mixed crystal having a ZnO crystal structure, or a mixed crystal having an NiO crystal structure.

Use of a Zn₁₋ₓNiₓO-based material allows for formation of a p-type semiconductor thin film at low temperature (e.g., 500° C. or below). This makes it possible to form an excellent heterojunction between a Zn₁₋ₓNiₓO layer and a ZnO layer. As such, p-type semiconductors made of a Zn₁₋ₓNiₓO-based material are suitable for a large-screen display. Specifically, a large-screen display can be formed by forming, on a substrate, a large number of p-type semiconductors made of a Zn₁₋ₓNiₓO-based material.

With the above structure, when driven, the semiconductor element 1X emits light of a wavelength in the range of the blue region to the ultraviolet region at the interface between the n-type semiconductor layer 3 and the first p-type semiconductor layer 4a.

### (Semiconductor Element 1)

FIG. 2 is a schematic sectional view showing the structure of a semiconductor element 1 according to Embodiment 1 of the present disclosure.

The semiconductor element 1 is based on the structure of the semiconductor element 1X, and includes the glass substrate 10, the lower electrode 2, the n-type semiconductor layer 3, the first p-type semiconductor layer 4a, a second p-type semiconductor layer 4b, and the upper electrode 5.

The lower electrode 2 is formed on the glass substrate 10, and is made of a material such as MO or ITO. The n-type semiconductor layer 3 is formed on the lower electrode 2. The n-type semiconductor layer 3 is an n-type ZnO layer that emits light at a band edge and has a thickness of several μm. The first p-type semiconductor layer 4a is formed on the n-type semiconductor layer 3, and is made of Zn_{0.5}Ni_{0.5}O which is a p-type semiconductor material according to the present disclosure as described above. The second p-type semiconductor layer 4b is one of the characteristic components of the semiconductor element 1, and is formed on the first p-type semiconductor layer 4a. The second p-type semiconductor layer 4b is made of Zn_{1-Y}Ni_{Y}O (0<Y≦1). Y is greater than X. In the present example, Y is 1, and the second p-type semiconductor layer 4b serves as a p-type NiO layer. The upper electrode 5 is made of a transparent electrode material, such as ITO, so that light is emitted from the top during the driving of the semiconductor element 1.

In the semiconductor element 1, a p-type semiconductor material is carefully selected so that an offset between the top of the valence band of the first p-type semiconductor layer 4a and the top of the valence band of the n-type semiconductor layer 3 is less than 1 eV. This prevents electrons in the vicinity of the top of the valence band of the first p-type semiconductor layer 4a from flowing toward the conduction band of the n-type ZnO layer during driving. This produces an effect of carrier recombination which contributes to light emission, thus improving the luminous efficiency.

An amount of NiO in ZnNiO that constitutes the first p-type semiconductor layer 4a is in the range of at least 20 mol % to less than 100 mol %, and more preferably in the range of at least 30 mol % to less than 100 mol %. In particular, it has been confirmed by the experiment in FIG. 6 that the first p-type semiconductor layer 4a achieves high performance when the amount of NiO contained therein is 50 mol %. Details of the experiment in FIG. 6 are described later.

Concerning the second p-type semiconductor layer 4b, the hole concentration thereof is at least 1×10¹⁷ cm⁻³ during driving. As such, the second p-type semiconductor layer 4b serves as a hole injection layer which favorably injects holes toward the n-type semiconductor layer 3. The semiconductor element 1 uses the second p-type semiconductor layer 4b to secure the hole concentration necessary for light emission.

With the aforementioned structure, when driven, the semiconductor element 1 according to Embodiment 1 externally emits light having a wavelength in the range of the blue region to the ultraviolet region with excellent luminous efficiency, in the vicinity of the interface between the n-type semiconductor layer 3 and the first p-type semiconductor layer 4a.

The first p-type semiconductor layer 4a and the second p-type semiconductor layer 4b can be thinly formed over large area at relatively low temperature in a manner that the first p-type semiconductor layer 4a and the second p-type semiconductor layer 4b both have surface smoothness. This realizes a light-emitting device with higher luminous efficiency than a conventional light-emitting device.

### <Observation>

(1) Position at the Top of the Valence Band

FIG. 3 shows a result of XPS measurement performed on thin films which are each made of one of ZnO, Zn_{0.5}Ni_{0.5}O, and NiO. Specifically, FIG. 3 shows a state of each of the thin films in the vicinity of the valence band. In FIG. 3, the horizontal axis represents spectra each showing the energy calibrated by C1s binding energy measurable at the same time during the XPS measurement.

The spectra in FIG. 3 each exhibit a rise in the region where the energy is less than 5 eV. Based on the rise of each spectrum, the correlation between the energy positions of the respective thin films at the top of the valence band is determined. As shown in these spectra, the offset between the top of the valence band of the ZnO thin film and the top of the valence band of the Zn_{0.5}Ni_{0.5}O thin film is relatively small, and falls within at least 1 eV. Based on this, it can be understood that holes are favorably moved from the Zn_{0.5}Ni_{0.5}O thin film to the ZnO thin film.

(2) Band Diagram of ZnO, NiO, and Zn_{0.5}Ni_{0.5}O

FIG. 4 is a band diagram of ZnO, NiO, and Zn₁₋ₓNiₓO. The band diagram is created based on the physical values of ZnO and NiO which are each a pure material, and on the measurement value of the optical band gap of the Zn_{0.5}Ni_{0.5}O thin film obtained as a result of an experiment. According to the data shown in FIG. 4, the energy value of ZnO at the top of the valence band is approximately 7.7 eV. The energy value of NiO at the top of the valence band is approximately 5.1 eV.

As shown in FIG. 4, the larger the value X in Zn₁₋ₓNiₓO, the larger the offset between the top of the valence band of Zn₁₋ₓNiₓO and the top of the valence band of ZnO. A large offset is problematic because when a ZnO layer and a Zn₁₋ₓNiₓO layer are joined to form a semiconductor element, the hole injection efficiency and the resistance against reverse bias voltage are lowered. Accordingly, it is desirable that the value X be small. It is desirable to set the value X to 0.65 or less, so that the offset between the top of the valence band of the Zn₁₋ₓNiₓO layer and the top of the valence band of the ZnO layer is less than 1 eV.

Let the electricity conduction type of the Zn₁₋ₓNiₓO layer be p-type. In this case, in order to reduce electric resistance in the p-type Zn₁₋ₓNiₓO layer, it is desirable that the value X be 0.13 or greater. However, in the case of a light-emitting device through which an electric current of greater than or equal to 10 mA/cm² flows, it is desirable that a sufficient amount of holes be injected.

(3) Resistivity of Zn₁₋ₓNiₓO-Based Thin Film

FIG. 5 is a graph showing: a result of measurement of resistivity of a Zn₁₋ₓNiₓO-based thin film; and an approximate curve L: ρ (resistivity)=10^{(-4·(X-1)-0.5)}. As shown in FIG. 5, in order to suppress resistance, it is desirable that the value X in a Zn₁₋ₓNiₓO-based material be close to 1.

Suppose that resistibility against reverse bias voltage is prioritized in view of application to an optical sensor or the like, and the semiconductor element including a Zn₁₋ₓNiₓO thin film is used as a low current device. In this case, it is desirable to use a Zn₁₋ₓNiₓO thin film material where X=0.65 or less. On the other hand, suppose that the hole injection efficiency is prioritized over the resistibility against reverse bias voltage, as seen in the case where the semiconductor element is used for LED lighting, etc. In this case, it is desirable to use a Zn₁₋ₓNiₓO thin film material where X=0.65 or greater.

Furthermore, suppose that the semiconductor element is applied to a device such as a display. In this case, it is desirable to maintain both excellent hole injection efficiency and excellent resistibility against reverse bias voltage. Accordingly, it is desirable to use a Zn₁₋ₓNiₓO thin film material where X is appropriately set in view of a tradeoff between the hole injection efficiency and the resistibility against reverse bias voltage and according to the specifications of the device.

(4) Satisfying Both Hole Injection Efficiency and Resistibility Against Reverse Bias

Next, the present inventors conducted an intensive study on a p-type semiconductor layer that satisfies both hole injection efficiency and resistibility against reverse bias voltage. The study was conducted with use of a Zn_{0.5}Ni_{0.5}O thin film where X=approximately 0.65. Such a Zn_{0.5}Ni_{0.5}O thin film is considered to satisfy both hole injection efficiency and resistibility against reverse bias voltage. The study was conducted to determine whether such a Zn_{0.5}Ni_{0.5}O thin film has a potential to achieve the following two functions.

1) Function as a hole injection layer

2) Function as an intermediate layer which assists hole injection from an NiO thin film, the NiO thin film having the highest hole injection properties in the state where there is no potential barrier caused by a valence band offset.

Specifically, the capability of injecting holes into the ZnO active layer was estimated based on calculation. The calculation was performed as follows. First, as shown in FIG. 5, composition (X) dependence, which is the dependence of the resistance of the Zn₁₋ₓNiₓO-based thin film on the composition thereof, was obtained through an experiment and was expressed by the approximate curve L: ρ (resistivity)=10^{(-4·(X-1)-0.5)}. Then, a potential barrier φ₁₂ (a valence band offset between a material 1 and a material 2) was used to express exp (φ₁₂/kT·A) (k: Boltzmann constant, T: absolute temperature, A: constant). With this exp (φ₁₂/kT·A), an influence of the existing potential barrier on the hole injection resistance was examined. FIG. 6 is a graph showing a result of the examination. In FIG. 6, a curve 1 (solid line) is a calculation result of the X dependence of a ZnO/Zn₁₋ₓNiₓO/NiO structure in which a ZnO layer, a Zn₁₋ₓNiₓO layer, and an NiO layer are formed in the stated order. A curve 2 (dashed line) is a calculation result of the X dependence of a ZnO/Zn₁₋ₓNiₓO/Zn_{0.5}Ni_{0.5}O structure in which a ZnO layer, a Zn₁₋ₓNiₓO layer, and a Zn_{0.5}Ni_{0.5}O layer are formed in the stated order.

As can be seen from the curve 2, the insertion of the Zn₁₋ₓNiₓO layer (X<0.5) between the ZnO active layer and the Zn_{0.5}Ni_{0.5}O layer does not improve the hole injection conductance (corresponding to the hole injection capability). However, in the case of the curve 1 indicating a calculation result when the Zn₁₋ₓNiₓO layer (X=0 to 1) is inserted between the ZnO layer and the NiO layer, it can be understood that the hole injection conductance is at a maximum near the region where X=0.5, and the hole injection capability is improved as compared to each of the NiO single layer and the Zn_{0.5}Ni_{0.5}O single layer.

In other words, a ZnO/Zn_{0.5}Ni_{0.5}O/NiO structure in which a ZnO layer, a Zn_{0.5}Ni_{0.5}O layer, and a NiO layer are formed in the stated order can most effectively inject holes into the ZnO active layer. Furthermore, in the ZnO/Zn_{0.5}Ni_{0.5}O/NiO structure, a p-n junction interface is formed by the ZnO active layer (n-type) and the Zn_{0.5}Ni_{0.5}O layer (p-type). As such, a semiconductor element including this structure can maintain the resistibility against reverse bias voltage.

From the results shown in FIG. 6, it can be understood that a first p-type semiconductor layer made of a Zn₁₋ₓNiₓO-based material where X is in the range of 0.3≦X<1 is higher in hole injection conductance than an NiO layer not including Zn. In other words, it is desirable that X be in the range of 0.3≦X<1 (an amount of NiO in ZnNiO is in the range of at least 30 mol % to less than 100 mol %).

### <Experiment>

Hole mono-carrier elements (i.e., elements in which holes are dominant carriers that contribute to current transport) each having a different structure as shown in FIG. 7 were manufactured by forming films through a sputtering method. Based on the hole mono-carrier elements, verification was performed on the result of the calculation shown in FIG. 6.

The hole mono-carrier elements used for the verification are an NiO/ZnO/NiO element, an NiO/ZnO/Zn_{0.5}Ni_{0.5}O element, and an NiO/ZnO/Zn_{0.5}Ni_{0.5}O/NiO element. Each of these elements includes a lower electrode and an upper electrode that are made of ITO. FIG. 8 shows a result of the verification using the hole mono-carrier elements.

The result shown in FIG. 8 matches qualitatively with the result of the calculation shown in FIG. 6.

In FIG. 8, current values A, B, and C in the respective hole mono-carrier elements indicate current values when the applied voltage is 3 V. Based on the current values A, B, and C, current ratios B/A and C/B were obtained, and a point A in FIG. 8 was matched with the current value at a point A of the curve 1 in FIG. 6 at which X=0.5. Also, based on the current ratios B/A and C/B and the current value at the point A in FIG. 6, a point B was plotted at the point where X=1.0 in FIG. 6, and a point C was plotted at the point where X=0.5 in FIG. 6. This result sufficiently supports the result of the calculation in FIG. 6, although there is a slight quantitative divergence therebetween. Based on the result of the calculation, it can be understood that a Zn₁₋ₓNiₓO layer (X>0.3) is suitable as an intermediate layer between the ZnO layer and the NiO layer, and that X=0.5 is the most favorable value.

Also, based on a result of the experiment, it can be understood that in the first p-type semiconductor layer made of a Zn₁₋ₓNiₓO-based material, the most appropriate value for X is 0.5. In view of this, X may be set to the range of 0.45≦X≦0.55, so that the advantageous effect produced by the semiconductor element including the first p-type semiconductor layer is particularly significant.

### <Additional Matters>

As described above, it is determined from the result shown in FIG. 4, etc., that X in the Zn_{1-X}Ni_{X}O of the first p-type semiconductor layer 4a is desirably 0.65 or less from the viewpoint of suppressing the offset between the top of the valence band of the first p-type semiconductor layer 4a and the top of the valence band of the n-type semiconductor layer 3. On the other hand, it is determined from the result of FIG. 6, etc., that X in the Zn₁₋ₓNiₓO of the first p-type semiconductor layer 4a is desirably 0.3 or greater from the viewpoint of achieving a high hole injection capability. To satisfy both of the objectives above, it may be desirable that X in the Zn₁₋ₓNiₓO of the first p-type semiconductor layer 4a is in the range of 0.3≦X≦0.65.

Note that Y in the Zn_{1-Y}Ni_{Y}O of the second p-type semiconductor layer 4b is not limited to 1, but may be smaller than 1 (i.e., the composition of the second p-type semiconductor layer 4b may include Zn). As described above, the second p-type semiconductor layer 4b may include a small amount of Zn. Even if the second p-type semiconductor layer 4b includes a small amount of Zn, the effect of the present disclosure is still achievable.

### INDUSTRIAL APPLICABILITY

The semiconductor element of the present disclosure is usable as a light-emitting device in a large-screen display device or the like.

### REFERENCE SIGNS LIST

1X, 1 Semiconductor element

2 Lower electrode

3 N-type semiconductor layer (ZnO layer)

4a First p-type semiconductor layer (Zn₁₋ₓNiₓO layer)

4b Second p-type semiconductor layer (Zn_{1-Y}Ni_{Y}O layer)

5 Upper electrode

10 Glass substrate

1. A semiconductor element comprising:
an n-type semiconductor layer made of ZnO;
a first p-type semiconductor layer that is on the n-type semiconductor layer and is made of Zn_{1-X}Ni_{X}O where 0<X<1; and
a second p-type semiconductor layer that is on the first p-type semiconductor layer and is made of Zn_{1-Y}Ni_{Y}O where 0<Y≦1, wherein
Y is greater than X, and
an amount of NiO in the first p-type semiconductor layer is in a range of at least 30 mol % to less than 100 mol %.

2. The semiconductor element of claim 1, wherein
X in the Zn_{1-X}Ni_{X}O of the first p-type semiconductor layer is in a range of 0<X≦0.65.

3. The semiconductor element of claim 1, wherein
X in the Zn_{1-X}Ni_{X}O of the first p-type semiconductor layer is in a range of 0.3≦X≦0.65.

4. The semiconductor element of claim 1, wherein
X in the Zn_{1-X}Ni_{X}O of the first p-type semiconductor layer is in a range of 0.45≦X≦0.55.

5. The semiconductor element of claim 1, wherein
Y in the Zn_{1-Y}Ni_{Y}O of the second p-type semiconductor layer is 1.

6. The semiconductor element of claim 1, wherein
an offset between a top of a valence band of the first p-type semiconductor layer and a top of a valence band of the n-type semiconductor layer is less than 1 eV.

7. The semiconductor element of claim 1, wherein
a hole concentration of the second p-type semiconductor layer is at least 1×10¹⁷ cm⁻³.
